(19) United States
(12) Patent Application Publication
(10) Pub. No.: US 2016/0225840 A1
(43) Pub. Date: Aug. 4, 2016

(54) DISPLAY AND ELECTRONIC APPARATUS

(71) Applicant: Sony Corporation, Tokyo (JP)

(72) Inventors: Junichi Yamashita, Tokyo (JP); Katsuhide Uchino, Kanagawa (JP)

(21) Appl. No.: 15/093,650

(22) Filed: Apr. 7, 2016

Related U.S. Application Data
(63) Continuation of application No. 14/797,438, filed on Jul. 13, 2015.
Application No. 14/797,438 is a continuation of application No. 12/081,927, filed on Apr. 23, 2008.

(30) Foreign Application Priority Data
May 11, 2007 (JP) 2007-126557

(51) Int. Cl. H01L 27/32; H01L 51/00

(52) U.S. Cl. CPC H01L 27/3276; H01L 51/0023; H01L 2227/323; H01L 2251/568

(57) ABSTRACT

A display includes: row interconnects configured to be disposed along rows; column interconnects configured to be disposed along columns; and pixels configured to be disposed corresponding to intersections of the row and column interconnects arranged in a lattice manner. Each of the pixels includes at least a sampling transistor, a drive transistor, a holding capacitor, and a light-emitting element. The sampling transistor is turned on in response to a control signal supplied from one of the interconnects to thereby sample a video signal supplied from another of the interconnects and write the video signal to the holding capacitor. The drive transistor supplies the light-emitting element with a drive current dependent upon the video signal written to the holding capacitor.

### CROSS REFERENCES TO RELATED APPLICATIONS

This is a Continuation of U.S. patent application Ser. No. 14/797,438 filed on Jul. 13, 2015, which is a Continuation of U.S. patent application Ser. No. 12/081,927 filed on Apr. 23, 2008, which in turn claims priority from Japanese Patent Application Number JP2007-126557 filed in the Japan Patent Office on May 11, 2007, the entire contents of which being incorporated herein by reference.

### BACKGROUND OF THE INVENTION

1. Field of the Invention

The present invention relates to an active-matrix display including light-emitting elements in its pixels. Furthermore, the present invention relates to electronic apparatus including this kind of display. More specifically, the present invention relates to a technique for repairing a short-circuit defect of interconnects integrally formed in a display.

2. Description of Related Art

In recent years, development of flat self-luminous displays employing organic EL devices as light-emitting elements is being actively promoted. The organic EL device is based on a phenomenon that an organic thin film emits light in response to application of an electric field thereto. The organic EL device can be driven by application voltage of 10 V or lower, and thus has low power consumption. Furthermore, because the organic EL device is a self-luminous element that emits light by itself, it does not need an illuminating unit and thus can easily achieve reduction in the weight and thickness of a display. Moreover, the response speed of the organic EL device is as very high as about several microseconds, which causes no image lag in displaying of a moving image.

Among the flat self-luminous displays employing the organic EL devices for the pixels, particularly an active-matrix display in which thin film transistors are integrally formed as drive elements in the respective pixels is being actively developed. Active-matrix flat self-luminous displays are disclosed in e.g. Japanese Patent Laid-open Nos. 2003-255856, 2003-271095, 2004-133240, 2004-029791, and 2004-093682.

Basically, the active-matrix display includes row interconnects disposed along rows, column interconnects disposed along columns, and pixels disposed corresponding to the respective intersections of both the interconnects arranged in a lattice manner. Each of the pixels includes at least a sampling transistor, a drive transistor, a holding capacitor, and a light-emitting element. The sampling transistor is turned on in response to a control signal supplied from an interconnect to thereby sample a video signal supplied from another interconnect and write the video signal to a holding capacitor. The drive transistor supplies the light-emitting element with a drive current dependent upon the video signal written to the holding capacitor.

In this configuration, the row and column interconnects are often formed of the same conductive layer. Enhancement in the definition and function of displays requires decrease in the resistance of the interconnects. To meet this requirement, both the row and column interconnects are formed of the same conductive layer composed of a low-resistance material such as aluminum. In this case, at the intersection of the row and column interconnects, one interconnect is cut away, and the other interconnect is so formed as to cross the one interconnect in such a manner as to pass through the absent part arising from the cutting-away of the one interconnect. Furthermore, the pair of ends of the one interconnect, facing each other across the absent part, are connected to each other by a different interconnect serving as a bridge for the connection. In the present specification, this different interconnect serving as a bridge will be often referred to as a bridge interconnect.

The bridge interconnect is formed of a different conductive layer isolated from the row and column interconnects by an interlayer insulating film. This bridge interconnect connects the pair of ends of the one interconnect to each other through the shortest distance, and thus overlaps with the absent part in plan view.

The row and column interconnects are formed of the same conductive layer as described above, and are obtained by patterning of the same etching process. The etching treatment often causes a short-circuit defect between the interconnects due to so-called etching residue and attaching of foreign matter (dust). In particular, the intersection of the row and column interconnects involves pattern complexity and small distance between both the interconnects, and therefore the short-circuit defect occurs at the intersection more frequently compared with other areas stochastically.

In order to improve the display yield, a technique of burning out a short-circuit defect by laser light irradiation to thereby repair the defect is carried out. However, in a hitherto known display, the bridge interconnect is also formed just at the intersection, at which the short-circuit defect frequently occurs, and hence the repair treatment by laser light irradiation is often difficult. Specifically, when the bridge interconnect is formed of a lower conductive layer and the row and column interconnects are formed of an upper conductive layer for example, irradiation of the upper conductive layer with laser light for repairing a defect inevitably irradiates the lower conductive layer with the laser light, which possibly damages the lower conductive layer and hence induces another defect.

### SUMMARY OF THE INVENTION

There is a need for the present invention to provide a display having an interconnect layout that allows easy repairing of a short-circuit defect even at the intersection of row and column interconnects. According to an embodiment of the present invention, there is provided a display including row interconnects configured to be disposed along rows, column interconnects configured to be disposed along columns, and pixels configured to be disposed corresponding to the intersections of the row and column interconnects arranged in a lattice manner. Each of the pixels includes at least a sampling transistor, a drive transistor, a holding capacitor, and a light-emitting element. The sampling transistor is turned on in response to a control signal supplied from one of the interconnects to thereby sample a video signal supplied from another of the interconnects and write the video signal to the holding capacitor. The drive transistor supplies the light-emitting element with a drive current dependent upon the video signal written to the holding capacitor. The row interconnects and the column interconnects are formed of the same conductive layer. At the intersection of the row and column interconnects, one interconnect is cut away, and the other interconnect crosses the one interconnect in such a manner as to pass through an absent part arising from the cutting-away of the one interconnect. A pair of ends of the one interconnect, facing each other across the absent part, are connected to each other by a different interconnect. The different interconnect is formed of a different conductive layer isolated from the row and column interconnects by an interlayer insulating film. The different interconnect intersects with the other interconnect in such a manner as to avoid the absent part, to thereby permit repairing of a short-circuit defect between the end of the one interconnect and the other interconnect, caused at the absent part.

According to this embodiment of the present invention, a bridge interconnect is so disposed as to intersect with the other interconnect in such a manner as to avoid the absent part of the one interconnect. In other words, the bridge interconnect is so laid out as to bypass the intersection of the row and column interconnects. Thus, the bridge interconnect does not exist at the intersection, at which a short-circuit defect frequently occurs stochastically. Consequently, when a short-circuit defect between an end of the one interconnect and the other interconnect is caused at the intersection of these interconnects, this short-circuit defect can be repaired by laser light irradiation with no any damage to the bridge interconnect. This can improve the display yield.

### BRIEF DESCRIPTION OF THE DRAWINGS

FIG. 1 is a block diagram showing the entire configuration of an existing display;

FIG. 2 is a circuit diagram showing one example of a pixel circuit included in the display shown in FIG. 1;

FIG. 3 is a circuit diagram showing a display according to a first embodiment of the present invention;

FIG. 4 is a schematic diagram for explaining the first embodiment;

FIG. 5 is a schematic diagram for explaining the first embodiment;

FIG. 6 is a schematic diagram for explaining the first embodiment;

FIG. 7 is a circuit diagram showing a display according to a first reference example;

FIG. 8 is a schematic diagram for explaining the first reference example;

FIG. 9 is a schematic diagram for explaining the first reference example;

FIG. 10 is a timing chart for explaining the operation of the display according to the first embodiment;

FIG. 11 is a block diagram showing another example of a display according to a related art;

FIG. 12 is a circuit diagram showing the configuration of a pixel circuit included in the display shown in FIG. 11;

FIG. 13 is a circuit diagram showing a display according to a second embodiment of the present invention;

FIG. 14 is a schematic diagram for explaining the second embodiment;

FIG. 15 is a schematic diagram for explaining the second embodiment;

FIG. 16 is a circuit diagram showing a display according to a second reference example;

FIG. 17 is a schematic diagram for explaining the second reference example;

FIG. 18 is a circuit diagram for explaining the operation of the display according to the second embodiment;

FIG. 19 is a timing chart for explaining the operation of the second embodiment;

FIG. 20 is a sectional view showing the device structure of the displays according to the embodiments;

FIG. 21 is a plan view showing the module structure of the displays according to the embodiments;

FIG. 22 is a perspective view showing a television set including the display according to any of the embodiments;

FIG. 23 is a perspective view showing a digital still camera including the display according to any of the embodiments;

FIG. 24 is a perspective view showing a notebook personal computer including the display according to any of the embodiments;

FIG. 25 is a schematic diagram showing a portable terminal device including the display according to any of the embodiments; and

FIG. 26 is a perspective view showing a video camera including the display according to any of the embodiments.

### DETAILED DESCRIPTION OF THE PREFERRED EMBODIMENTS

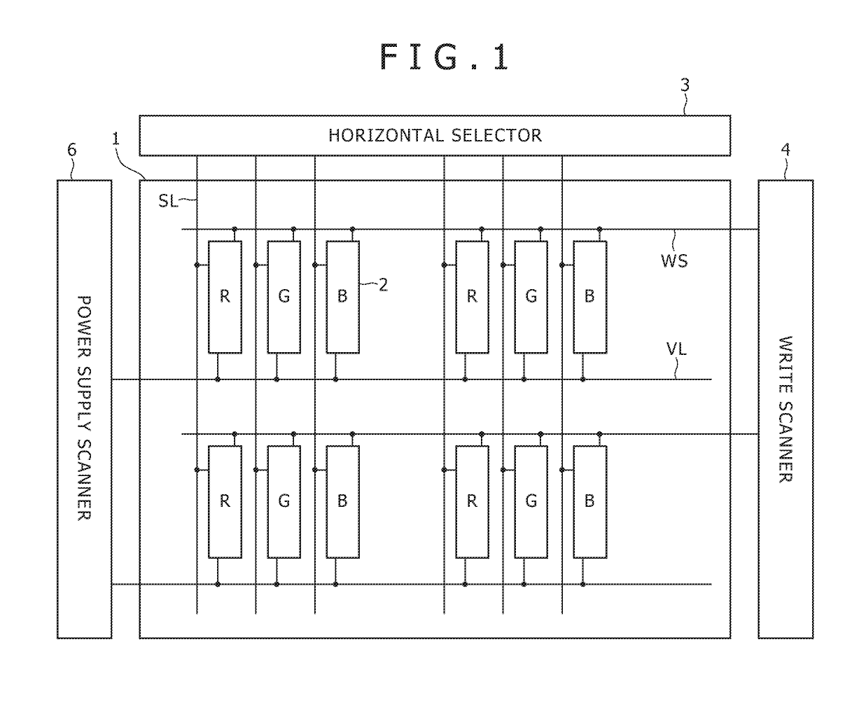

Embodiments of the present invention will be described below in detail with reference to the accompanying drawings. Initially, to clearly show the background of the present invention, an existing display as the basis for the embodiments will be described below as part of the present invention. FIG. 1 is a block diagram showing the entire configuration of the existing display. As shown in FIG. 1, this display includes a pixel array part 1 and a drive part for driving the pixel array part 1. The pixel array part 1 includes row scan interconnects WS, column signal interconnects (signal lines) SL, pixels 2 disposed at the intersections of both the interconnects so as to be arranged in a matrix, and power supply interconnects (power supply lines) VL disposed corresponding to the respective rows of the pixels 2. In the present example, any of the three primary colors of R, G, and B is allocated to each of the pixels 2, and thus color displaying is possible. However, the display is not limited thereto but encompasses devices of single-color displaying. The drive part includes a write scanner 4, a power supply scanner 6, and a signal selector (horizontal selector) 3. The write scanner 4 sequentially supplies a control signal to the respective scan interconnects WS to thereby line-sequentially scan the pixels 2 on a row-by-row basis. The power supply scanner 6 provides a supply voltage whose level is switched between first potential and second potential to the respective power supply interconnects VL in matching with the line-sequential scanning. The signal selector 3 supplies a signal potential as a video signal and a reference potential to the column signal interconnects SL in matching with the line-sequential scanning.

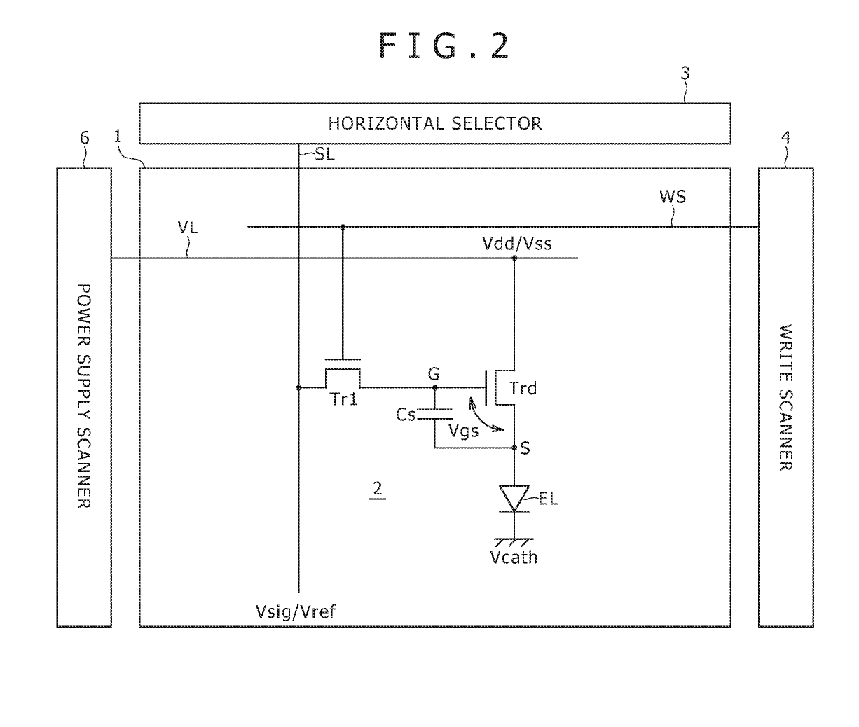

FIG. 2 is a circuit diagram showing the specific configuration and connection relationship of the pixel 2 included in the display shown in FIG. 1. As shown in FIG. 2, the pixel 2 includes a light-emitting element EL typified by an organic EL device, a sampling transistor Tr1, a drive transistor Trd, and a holding capacitor Cs. The control terminal (gate) of the sampling transistor Tr1 is connected to the corresponding scan interconnect WS. One of a pair of current terminals (source and drain) of the sampling transistor Tr1 is connected to the corresponding signal interconnect SL, and the other is connected to the control terminal (gate G) of the drive transistor Trd. One of a pair of current terminals (source S and drain) of the drive transistor Trd is connected to the light-emitting element EL, and the other is connected to the corresponding power supply interconnect VL. In the present example, the drive transistor Trd is an N-channel transistor. The drain thereof is connected to the power supply interconnect VL, and the source S thereof is connected as the output node to the anode of the light-emitting element EL. The cathode of the light-emitting element EL is connected to a predetermined cathode potential Vcath. The holding capacitor Cs is connected between the source S and gate G of the drive transistor Trd.

In this configuration, the sampling transistor Tr1 is turned on in response to the control signal supplied from the scan interconnect WS, to thereby sample the signal potential supplied from the signal interconnect SL and hold the sampled potential in the holding capacitor Cs. The drive transistor Trd receives current supply from the power supply interconnect VL at the first potential (higher potential Vdd) and applies a drive current to the light-emitting element EL depending on the signal potential held in the holding capacitor Cs. The write scanner 4 outputs the control signal having a predetermined pulse width to the scan interconnect WS so that the sampling transistor Tr1 may be kept at the conductive state in the time zone during which the signal interconnect SL is at the signal potential. Thereby, the signal potential is held in the holding capacitor Cs, and simultaneously with this, correction relating to the mobility μ of the drive transistor Trd is added to the signal potential. Thereafter, the drive transistor Trd supplies the light-emitting element EL with the drive current dependent upon the signal potential Vsig written to the holding capacitor Cs, which starts light-emission operation.

This pixel circuit 2 has a threshold voltage correction function in addition to the above-described mobility correction function. Specifically, the power supply scanner 6 switches the potential of the power supply interconnect VL from the first potential (higher potential Vdd) to the second potential (lower potential Vss) at a first timing before the sampling of the signal potential Vsig by the sampling transistor Tr1. Furthermore, the write scanner 4 turns on the sampling transistor Tr1 at a second timing before the sampling of the signal potential Vsig by the sampling transistor Tr1, to thereby apply the reference potential Vref from the signal interconnect SL to the gate G of the drive transistor Trd and set the source S of the drive transistor Trd to the second potential (Vss). The power supply scanner 6 switches the potential of the power supply interconnect VL from the second potential Vss to the first potential Vdd at a third timing after the second timing, to thereby hold the voltage equivalent to the threshold voltage Vth of the drive transistor Trd in the holding capacitor Cs. This threshold voltage correction function allows the display to cancel the influence of variation in the threshold voltage Vth of the drive transistor Trd from pixel to pixel.

The pixel circuit 2 further has a bootstrap function. Specifically, at the timing when the signal potential Vsig is held in the holding capacitor Cs, the write scanner 4 stops the application of the control signal to the scan interconnect WS to thereby turn off the sampling transistor Tr1 and thus electrically isolate the gate G of the drive transistor Trd from the signal interconnect SL. Due to this operation, the potential of the gate G changes in linkage with change in the potential of the source S of the drive transistor Trd, which allows the voltage Vgs between the gate G and the source S to be kept constant.

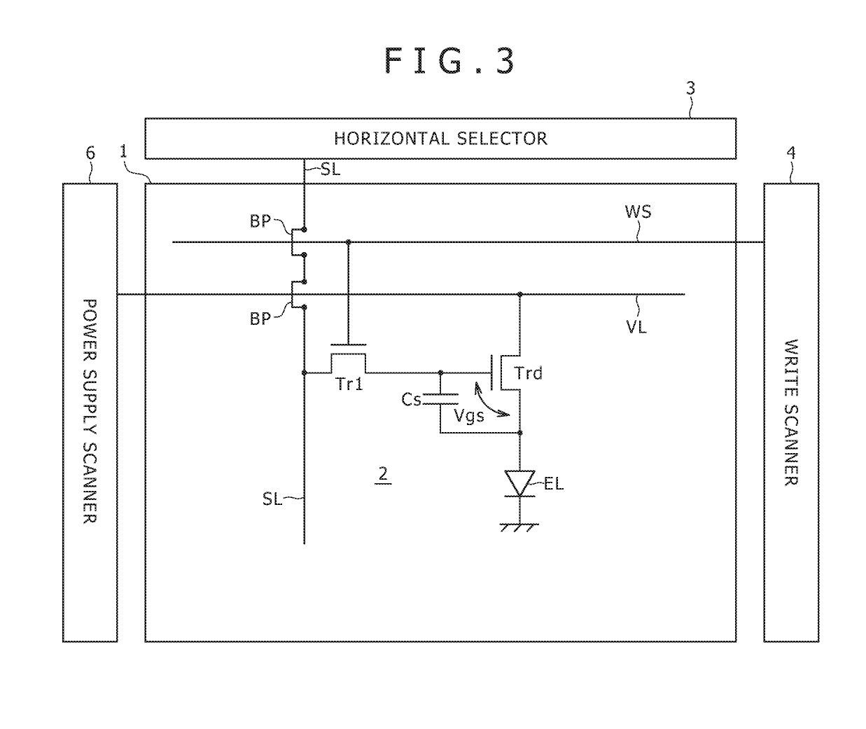

FIG. 3 is a circuit diagram showing a display according to a first embodiment of the present invention. The same parts in FIG. 3 as those in the existing display shown in FIG. 2 are given the same numerals for easy understanding. The basic configuration of the present embodiment is the same as that of the existing display. However, in the present embodiment, the interconnect pattern is improved to permit a short-circuit defect to be easily repaired through laser light irradiation.

The pixel array part 1 of this display includes the row scan interconnects WS, the column signal interconnects SL, and the pixels 2 disposed corresponding to the respective intersections of both the interconnects arranged in a lattice manner. Each of the pixels 2 includes at least the sampling transistor Tr1, the drive transistor Trd, the holding capacitor Cs, and the light-emitting element EL. The sampling transistor Tr1 is turned on in response to a control signal supplied from the scan interconnect WS to thereby sample a video signal supplied from the signal interconnect SL and write the video signal to the holding capacitor Cs. The drive transistor Trd supplies the light-emitting element EL with a drive current dependent upon the video signal written to the holding capacitor Cs.

The row scan interconnects WS and the column signal interconnects SL are formed of the same conductive layer. As described above, each pixel 2 in this display has the threshold voltage correction function, the mobility correction function, and the bootstrap function, and therefore has complex operation sequence. To carry out such operation sequence without error, it is preferable that the waveform distortion of the control signal supplied from the write scanner 4 to the scan interconnect WS is as small as possible. For this reason, the scan interconnect WS is formed of a low-resistance conductive layer composed of e.g. aluminum metal. In addition, the potential of the signal interconnect SL is also switched at high speed between signal potential and reference potential in order to carry out the complex operation sequence. To surely carry out such operation, the signal interconnect SL is formed of the same low-resistance conductive layer, composed of e.g. metal aluminum, as that of the scan interconnect WS.

Because the row scan interconnects WS and the column signal interconnects SL are formed of the same conductive layer, it is impossible that both the interconnects simply intersect with each other, unlike the related-art example shown in FIG. 2. Therefore, in the present embodiment, one interconnect SL is cut away at the intersection of the interconnects WS and SL. The other interconnect WS is so formed as to cross the one interconnect SL in such a manner as to pass through the absent part arising from the cutting-away of the one interconnect SL. Furthermore, the pair of ends of the one interconnect SL, facing each other across the absent part, are connected to each other by a bridge interconnect BP. The bridge interconnect BP is formed of a different conductive layer isolated from the row and column interconnects WS and SL by an interlayer insulating film. The bridge interconnect BP can be formed as a high-resistance interconnect composed of e.g. metal molybdenum. A feature of the present embodiment is that this bridge interconnect BP is so disposed as to intersect with the scan interconnect WS in such a manner as to avoid the absent part of the signal interconnect SL. Due to this layout, when a short-circuit defect between an end of the one interconnect SL and the other interconnect WS is caused at the absent part, this short-circuit defect can be easily repaired by laser light irradiation. Because the bridge interconnect BP bypasses the intersection of the signal interconnect SL and the scan interconnect WS as shown in FIG. 3, the short-circuit defect caused at the intersection can be repaired by laser light irradiation with no any damage to the bridge interconnect BP.

In some cases, the short-circuit defect is attributed to etching residue between the end of the one interconnect SL and the other interconnect WS, if the interconnects WS and SL are formed through etching. For these cases, the bridge interconnect BP is so formed as to bypass the absent part of the signal interconnect SL so that the short-circuit defect attributed to the etching residue can be eliminated by laser light irradiation. Alternatively, in other cases, the short-circuit defect is attributed to foreign matter (dust) attached to the absent part. Also for these cases, the bridge interconnect BP is so laid out as to bypass the absent part so that the short-circuit defect attributed to the foreign matter attached to the absent part can be eliminated by laser light irradiation.

In the present embodiment, the row interconnects include power supply interconnects VL for providing a supply voltage to the respective pixels 2 in addition to the scan interconnects WS for supplying the control signal to the respective pixels 2. This power supply interconnect VL is formed of the same low-resistance conductive layer as that of the scan interconnect WS and the signal interconnect SL. Because the power supply interconnects VL are to supply the drive current to the respective pixels 2, it is preferable that the voltage drop along this interconnect be as small as possible. For this reason, the low-resistance conductive layer is employed for the power supply interconnect VL. Therefore, also at the intersection of the signal interconnect SL and the power supply interconnect VL, the bridge interconnect BP is used for bridging. This bridge interconnect BP also intersects with the power supply interconnect VL in such a manner as to bypass the absent part of the signal interconnect SL.

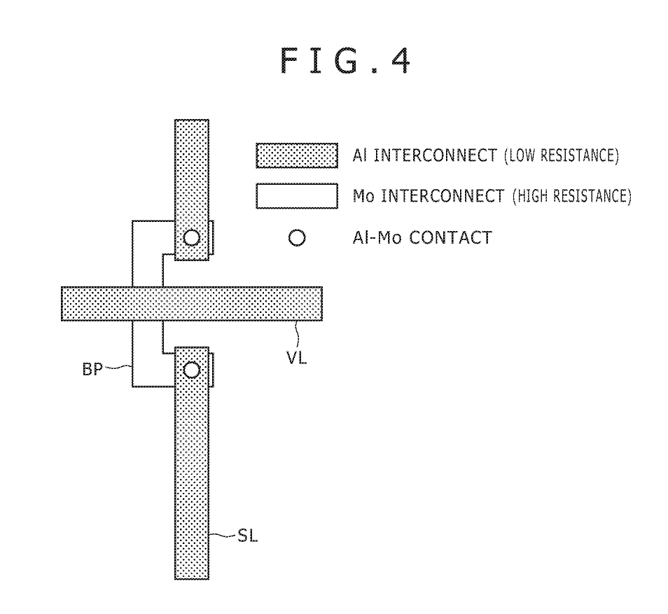

FIG. 4 is an enlarged plan view of an intersection included in the pixel array part in the display shown in FIG. 3. As shown in FIG. 4, the row power supply interconnect VL is formed of a low-resistance aluminum interconnect. The column signal interconnect SL is also formed of a low-resistance aluminum interconnect of the same layer. A partial portion of the column signal interconnect SL is cut away, and the row power supply interconnect VL crosses this absent part. The pair of ends of the signal interconnect SL, facing each other across the absent part, are connected to each other by the bridge interconnect BP. This bridge interconnect BP is formed of a high-resistance molybdenum interconnect separate from the low-resistance aluminum interconnect, and is electrically connected to the low-resistance aluminum interconnect of the separate layer via contact holes. As is apparent from FIG. 4, the bridge interconnect BP is so disposed as to bypass the intersection of the column signal interconnect SL and the row power supply interconnect VL.

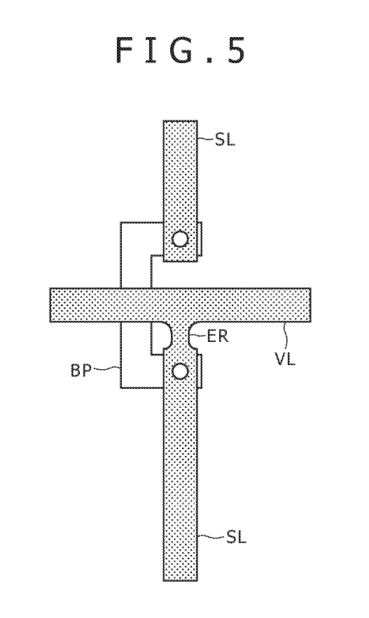

FIG. 5 is a schematic diagram showing a short-circuit defect ER caused at the intersection of the row power supply interconnect VL and the column signal interconnect SL. Because the pattern distance is small at the intersection of the interconnects SL and VL, the short-circuit defect ER due to etching residue frequently occurs at the intersection stochastically. In the example of FIG. 5, this short-circuit defect ER is caused between an end of the signal interconnect SL and a side part of the power supply interconnect VL. Due to the short-circuit defect ER, the power supply interconnect VL is electrically connected to the signal interconnect SL, which precludes the normal operation of the display.

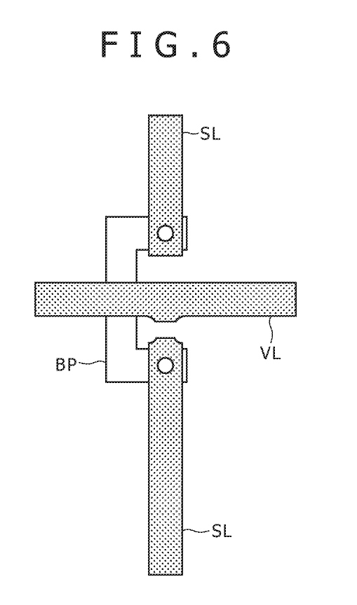

FIG. 6 is a schematic plan view showing treatment of repairing the short-circuit defect by laser light irradiation. As shown in FIG. 6, the short-circuit defect caused at the intersection of the signal interconnect SL and the power supply interconnect VL can be repaired by burning out it through laser light irradiation. The signal interconnect SL and the power supply interconnect VL are electrically isolated from each other by this repair treatment, so that the pixel array part can carry out normal operation. In this treatment, the bridge interconnect BP is not affected by the laser light irradiation because it bypasses the absent part of the signal interconnect SL. Thus, the short-circuit defect can be safely repaired with no any damage to the bridge interconnect BP.

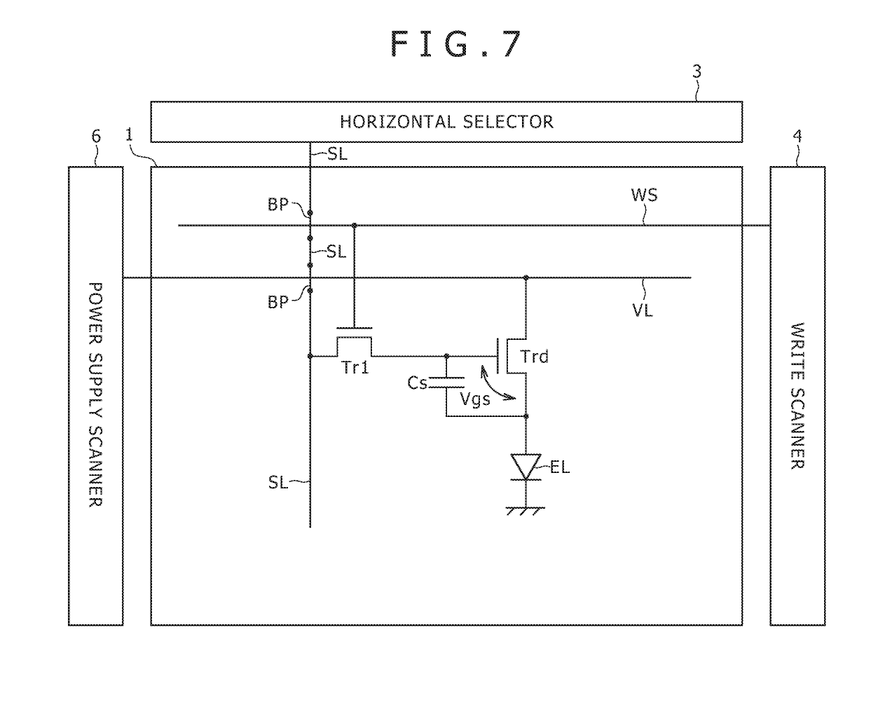

FIG. 7 is a schematic circuit diagram showing a first reference example of the display. Basically this example is similar to the first embodiment shown in FIG. 3, and therefore the same parts in FIG. 7 as those in FIG. 3 are given the same numerals for easy understanding. The difference therebetween is that the bridge interconnect BP does not bypass the intersection of the signal interconnect SL and the scan interconnect WS but is disposed on a straight line so as to be aligned with the signal interconnect SL. Similarly, another bridge interconnect BP is also disposed in alignment with the signal interconnect SL and intersects with the power supply interconnect VL.

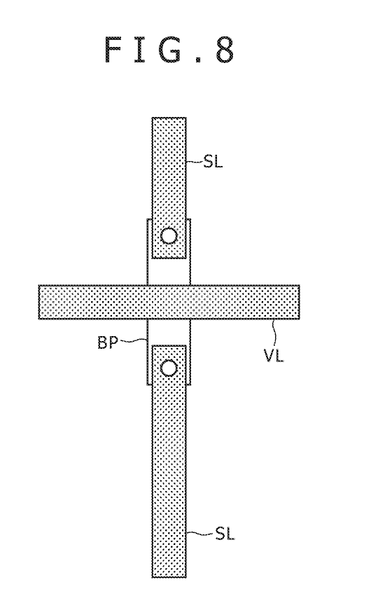

FIG. 8 is a schematic plan view showing the intersection of the signal interconnect SL and the power supply interconnect VL shown in FIG. 7. As shown in FIG. 8, the bridge interconnect BP connecting one pair of ends of the signal interconnect SL to each other does not have any bypass structure but is so formed along the shortest distance as to overlap with the absent part of the signal interconnect SL.

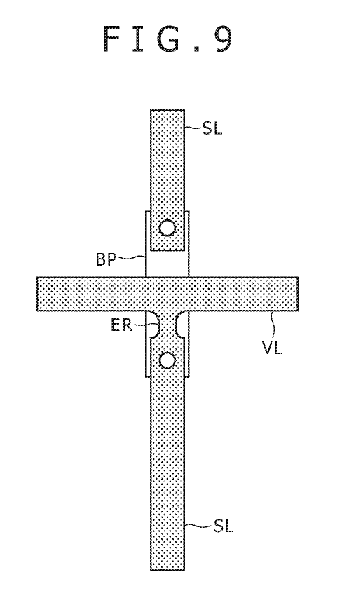

FIG. 9 is a schematic plan view showing a short-circuit defect ER caused at the intersection shown in FIG. 8. As described above, the intersection of the signal interconnect SL and the power supply interconnect VL is the area at which the short-circuit defect ER attributed to etching residue frequently occurs stochastically. In the example of FIG. 9, an end of the signal interconnect SL and a side part of the power supply interconnect VL are electrically connected to each other due to the short-circuit defect ER attributed to etching residue. In this case, laser light irradiation for repairing the short-circuit defect ER inevitably irradiates the bridge interconnect BP of a lower layer with the laser light, which possibly damages the bridge interconnect BP. In the worst case, the partial portions of the signal interconnect SL, vertically separated from each other across the power supply interconnect VL, will be electrically isolated from each other, which will preclude the normal operation of the pixel array part.

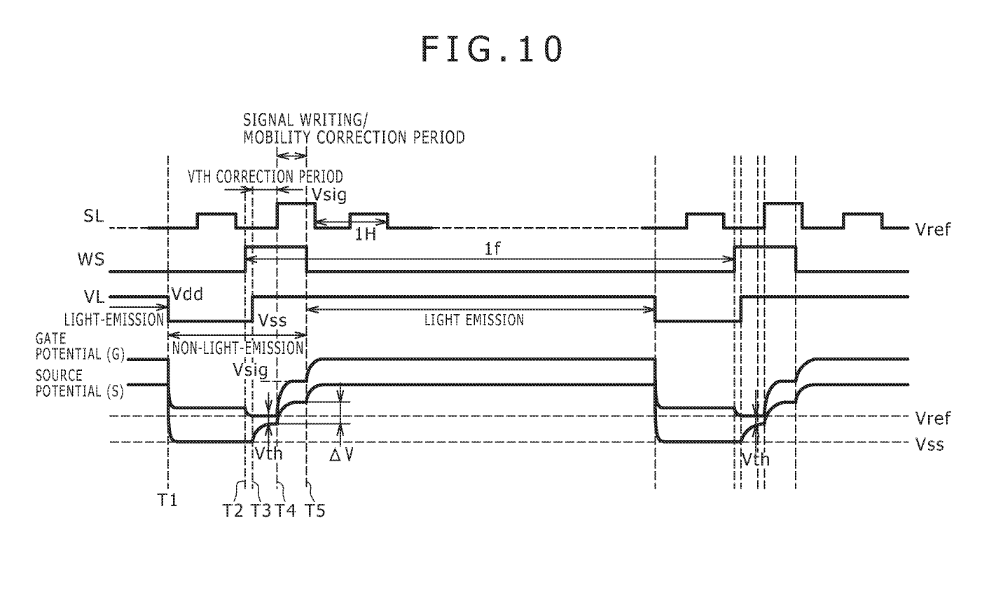

FIG. 10 is a timing chart for explaining the operation of the display according to the first embodiment shown in FIG. 3. In this timing chart, potential changes of the scan interconnect WS, the power supply interconnect VL, and the signal interconnect SL are shown along the same time axis. Furthermore, in parallel to these potential changes, potential changes of the gate G and source S of the drive transistor are also shown.

As described above, a control signal pulse for turning on the sampling transistor Tr1 is applied to the scan interconnect WS. This control signal pulse is applied to the scan interconnect WS with the one-field (1 f) cycle in matching with the line-sequential scanning of the pixel array part. The potential of the power supply interconnect VL is switched between higher potential Vdd and lower potential Vss with the one-field cycle likewise. The signal interconnect SL is provided with the video signal whose potential is switched between signal potential Vsig and reference potential Vref with a cycle of one horizontal period (1 H).

As shown in the timing chart of FIG. 10, the operation sequence of the pixel proceeds from the light-emission period of the previous field to the non-light-emission period of the description-subject field, and then enters the light-emission period of the description-subject field. In this non-light-emission period, preparation operation, threshold voltage correction operation, signal writing operation, and mobility correction operation are carried out.

In the light-emission period of the previous field, the power supply interconnect VL is at the higher potential Vdd, and the drive transistor Trd supplies a drive current Ids to the light-emitting element EL. The drive current Ids flows from the power supply interconnect VL at the higher potential Vdd via the drive transistor Trd and passes through the light-emitting element EL toward the cathode line.

Subsequently, upon the start of the non-light-emission period of the description-subject field, the potential of the power supply interconnect VL is initially switched from the higher potential Vdd to the lower potential Vss at a timing T1. Due to this operation, the power supply interconnect VL is discharged to Vss, so that the potential of the source S of the drive transistor Trd drops down to Vss. Thus, the anode potential (i.e., the source potential of the drive transistor Trd) of the light-emitting element EL enters the reverse-bias state, so that the flow of the drive current and hence the light emission are stopped. The potential of the gate G of the drive transistor also drops down in linkage with the potential drop of the source S.

Subsequently, at a timing T2, the potential of the scan interconnect WS is switched from the low level to the high level, so that the sampling transistor Tr1 enters the conductive state. At this time, the signal interconnect SL is at the reference potential Vref. Therefore, the potential of the gate G of the drive transistor Trd becomes the reference potential Vref of the signal interconnect SL via the conductive sampling transistor Tr1. At this time, the potential of the source S of the drive transistor Trd is at the potential Vss, which is sufficiently lower than Vref. In this way, initialization is so carried out that the voltage Vgs between the gate G and source S of the drive transistor Trd becomes higher than the threshold voltage Vth of the drive transistor Trd. The period T1-T3 from the timing T1 to a timing T3 is the preparation period in which the voltage Vgs between the gate G and source S of the drive transistor Trd is set higher than Vth in advance.

At the timing T3, the potential of the power supply interconnect VL is switched from the lower potential Vss to the higher potential Vdd, so that the potential of the source S of the drive transistor Trd starts rise-up. When the voltage Vgs between the gate G and source S of the drive transistor Trd has reached the threshold voltage Vth in due course, the current is cut off. In this way, the voltage equivalent to the threshold voltage Vth of the drive transistor Trd is written to the holding capacitor Cs. This corresponds to the threshold voltage correction operation. In order that the current does not flow to the light-emitting element EL but flows exclusively toward the holding capacitor Cs during the threshold voltage correction operation, the cathode potential Vcath is so designed that the light-emitting element EL is cut off during the threshold voltage correction operation. This threshold voltage correction operation is completed by the time the potential of the signal interconnect SL is switched from Vref to Vsig at a timing T4. Therefore, the period T3-T4 from the timing T3 to the timing T4 serves as the threshold voltage correction period.

At the timing T4, the potential of the signal interconnect SL is switched from the reference potential Vref to the signal potential Vsig. At this time, the sampling transistor Tr1 is continuously kept at the conductive state. Thus, the potential of the gate G of the drive transistor Trd becomes the signal potential Vsig. Because the light-emitting element EL is initially at the cut-off state (high-impedance state), the current that runs between the drain and source of the drive transistor Trd flows exclusively toward the holding capacitor Cs and the equivalent capacitor of the light-emitting element EL so as to start charging of these capacitors. By a timing T5, at which the sampling transistor Tr1 is turned off, the potential of the source S of the drive transistor Trd rises up by ΔV. In this way, the signal potential Vsig of the video signal is written to the holding capacitor Cs in such a manner as to be added to Vth, and the voltage ΔV for the mobility correction is subtracted from the voltage held in the holding capacitor Cs. Therefore, the period T4-T5 from the timing T4 to the timing T5 serves as the signal writing period/mobility correction period. In this manner, the writing of the signal potential Vsig and the adjustment by the correction amount ΔV are simultaneously carried out in the signal writing period T4-T5. The higher Vsig is, the larger the current Ids supplied by the drive transistor Trd and hence the absolute value of ΔV are. Consequently, the mobility correction dependent upon the light-emission luminance level is carried out. When Vsig is constant, higher mobility μ of the drive transistor Trd provides a larger absolute value of ΔV. In other words, higher mobility μ provides a larger amount ΔV of the negative feedback to the holding capacitor Cs. Therefore, variation in the mobility μ from pixel to pixel can be eliminated.

At the timing T5, the potential of the scan interconnect WS is switched to the low level as described above, so that the sampling transistor Tr1 enters the off-state. This isolates the gate G of the drive transistor Trd from the signal interconnect SL. Simultaneously, the flowing of the drain current Ids through the light-emitting element EL starts. This causes the anode potential of the light-emitting element EL to rise up depending on the drive current Ids. The rise-up of the anode potential of the light-emitting element EL is equivalent to the rise-up of the potential of the source S of the drive transistor Trd. If the potential of the source S of the drive transistor Trd rises up, the potential of the gate G of the drive transistor Trd also rises up in linkage with the rise-up of the potential of the source S due to the bootstrap operation of the holding capacitor Cs. The rise amount of the gate potential is equal to that of the source potential. Therefore, in the light-emission period, the voltage Vgs between the gate G and source S of the drive transistor Trd is kept constant. This voltage Vgs arises from the addition of the correction of the threshold voltage Vth and the mobility μ to the signal potential Vsig.

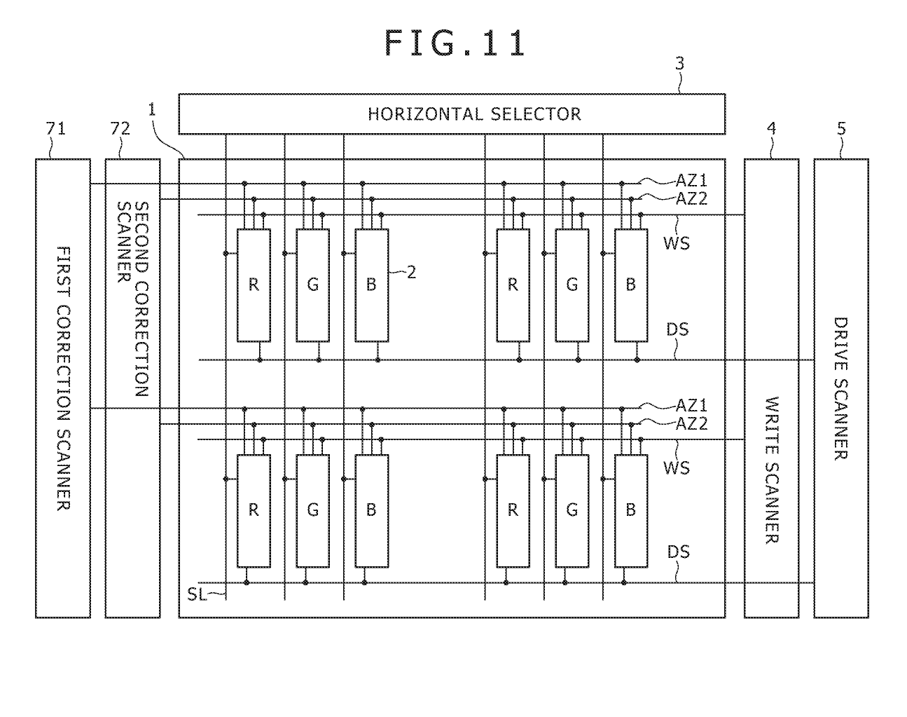

FIG. 11 is a schematic block diagram showing another example of an existing display. As shown in FIG. 11, this display is basically composed of a pixel array part 1, a scanner part, and a signal part. The pixel array part 1 includes first scan interconnects WS, second scan interconnects AZ1, third scan interconnects AZ2, and fourth scan interconnects DS that are disposed along the rows, and signal interconnects SL disposed along the columns. Furthermore, the pixel array part 1 includes pixel circuits 2 that are arranged in a matrix and are each connected to the scan interconnects WS, AZ1, AZ2, and DS, and the signal interconnect SL. In addition, the pixel array part 1 includes plural power supply interconnects for supplying first potential Vss1, second potential Vss2, and third potential Vcc necessary for the operation of the respective pixel circuits 2. The signal part includes a horizontal selector 3 and supplies a video signal to the signal interconnects SL. The scanner part includes a write scanner 4, a drive scanner 5, a first correction scanner 71, and a second correction scanner 72 that supply control signals to the first scan interconnects WS, the fourth scan interconnects DS, the second scan interconnects AZ1, and the third scan interconnects AZ2, respectively, for sequential scanning of the pixel circuits on a row-by-row basis.

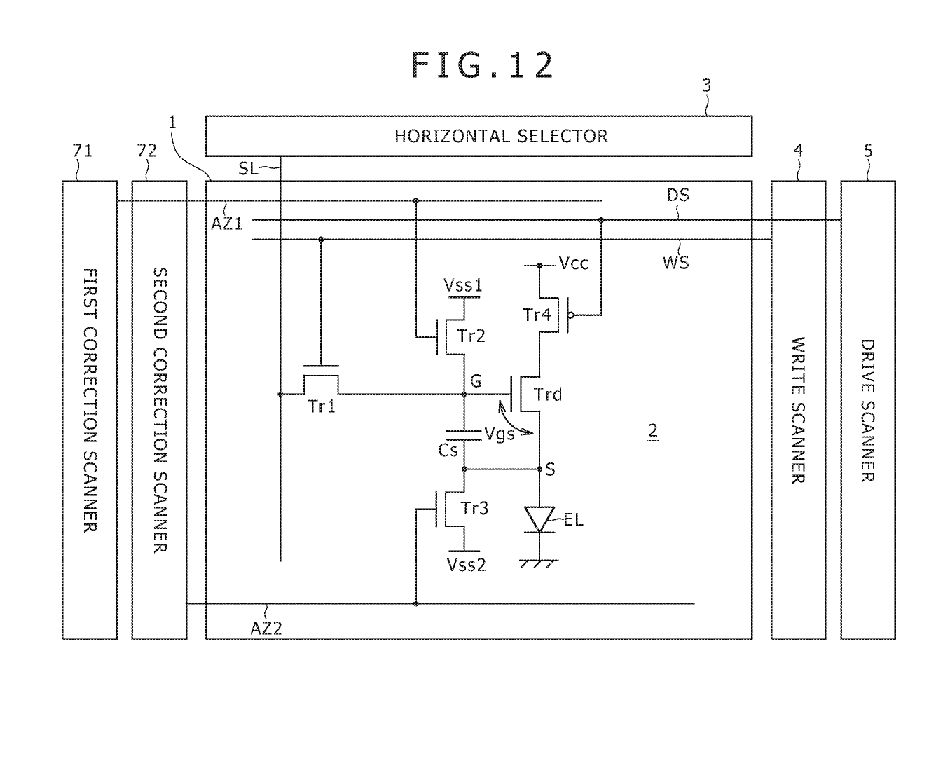

FIG. 12 is a circuit diagram showing a configuration example of the pixel circuit included in the display shown in FIG. 11. As shown in FIG. 12, the pixel circuit 2 includes a sampling transistor Tr1, a drive transistor Trd, a first switching transistor Tr2, a second switching transistor Tr3, a third switching transistor Tr4, a holding capacitor Cs, and a light-emitting element EL. The sampling transistor Tr1 is turned on in response to the control signal supplied from the first scan interconnect WS during a predetermined sampling period, to thereby sample the signal potential of the video signal supplied from the signal interconnect SL in the holding capacitor Cs. The holding capacitor Cs applies an input voltage Vgs to the gate G of the drive transistor Trd depending on the sampled signal potential of the video signal. The drive transistor Trd supplies an output current Ids corresponding to the input voltage Vgs to the light-emitting element EL. The output current Ids supplied from the drive transistor Trd during a predetermined light-emission period causes the light-emitting element EL to emit light with the luminance in accordance with the signal potential of the video signal.

The first switching transistor Tr2 is turned on in response to the control signal supplied from the second scan interconnect AZ1 before the sampling period, to thereby set the potential of the gate G of the drive transistor Trd to the first potential Vss1. The second switching transistor Tr3 is turned on in response to the control signal supplied from the third scan interconnect AZ2 before the sampling period, to thereby set the potential of the source S of the drive transistor Trd to the second potential Vss2. The third switching transistor Tr4 is turned on in response to the control signal supplied from the fourth scan interconnect DS before the sampling period, to thereby connect the drive transistor Trd to the third potential Vcc. This causes the holding capacitor Cs to hold the voltage equivalent to the threshold voltage Vth of the drive transistor Trd to thereby correct the influence of the threshold voltage Vth. In addition, this third switching transistor Tr4 is turned on in response to the control signal supplied from the fourth scan interconnect DS again during a light-emission period, to thereby connect the drive transistor Trd to the third potential Vcc. This allows the output current Ids to flow to the light-emitting element EL. In this pixel circuit 2, in the writing of the video signal to the holding capacitor Cs, mobility correction operation is carried out in a partial period of the sampling period. Specifically, as the operation, voltage for correcting variation in the mobility μ of the drive transistor Trd is negatively fed back to the holding capacitor Cs.

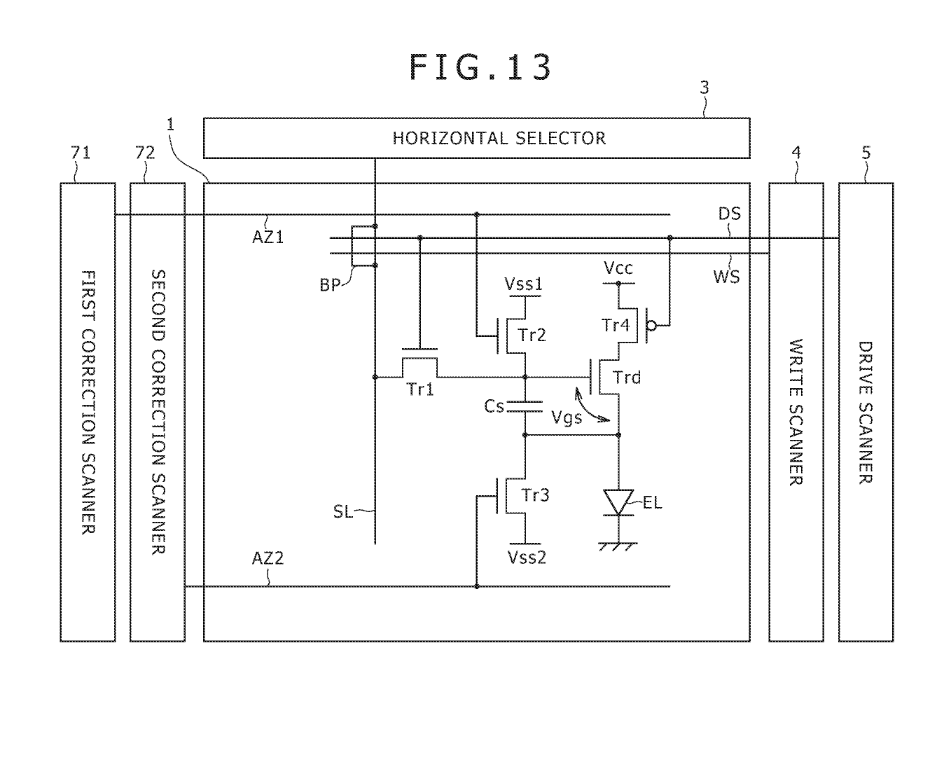

FIG. 13 is a circuit diagram showing a display according to a second embodiment of the present invention. Basically this display is similar to the existing display shown in FIG. 12, and therefore the same parts in FIG. 13 as those in FIG. 12 are given the same numerals. In order to accurately control the above-described threshold voltage correction operation and mobility correction operation, it is desirable that pulses of the control signals applied to the scan interconnects WS and DS have a sharp transient waveform. For the sharp transient waveform, the scan interconnects WS and DS along the horizontal direction of the panel should have low resistance. In addition, the signal interconnects SL should also sharply write the video signal in consideration of enhancement in the panel definition. Therefore, it is desirable that the signal interconnects SL along the column direction (vertical direction) also have low resistance. Consequently, in the present embodiment, the scan interconnects WS and DS and the signal interconnects SL are formed of the same layer. However, if the same layer is laid out along both the horizontal and vertical directions, short-circuit between the vertical and horizontal interconnects is caused at the intersections of these interconnects. To avoid this short-circuit in the present embodiment, at the intersection of the vertical and horizontal interconnects formed of the same layer, the vertical interconnect SL is partially cut away to thereby allow the horizontal interconnects WS and DS to pass through the cut-away part. Furthermore, a bridge interconnect BP is formed by a high-resistance different interconnect in order to connect the ends of the vertical interconnect SL, arising from the cut-away part, to each other. This bridge interconnect BP is so formed as to bypass the intersection of the vertical and horizontal interconnects. This feature allows easy repairing of a short-circuit defect between the vertical and horizontal interconnects, which frequently occurs at the intersection.

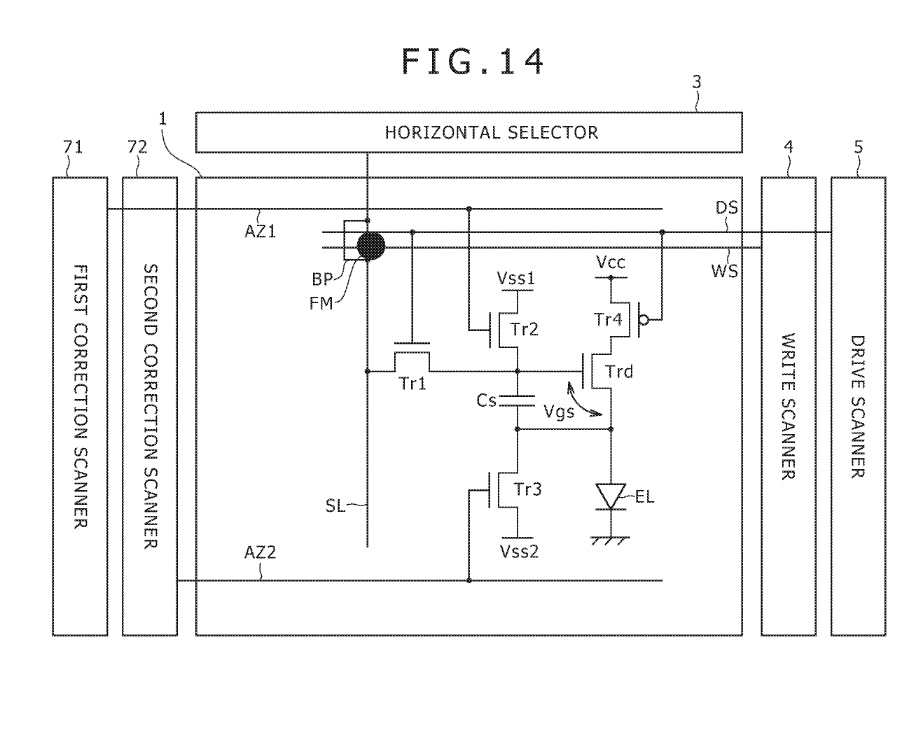

FIG. 14 shows the state in which a short-circuit defect FM is caused at intersections in the pixel array part in the display shown in FIG. 13. This short-circuit defect FM is attributed to the attaching of foreign matter such as a dust in the manufacturing process. Specifically, due to the attaching of foreign matter just on an end of the signal interconnect SL and the scan interconnects WS and DS, the short-circuit defect is caused between the signal interconnect SL and the scan interconnects WS and DS.

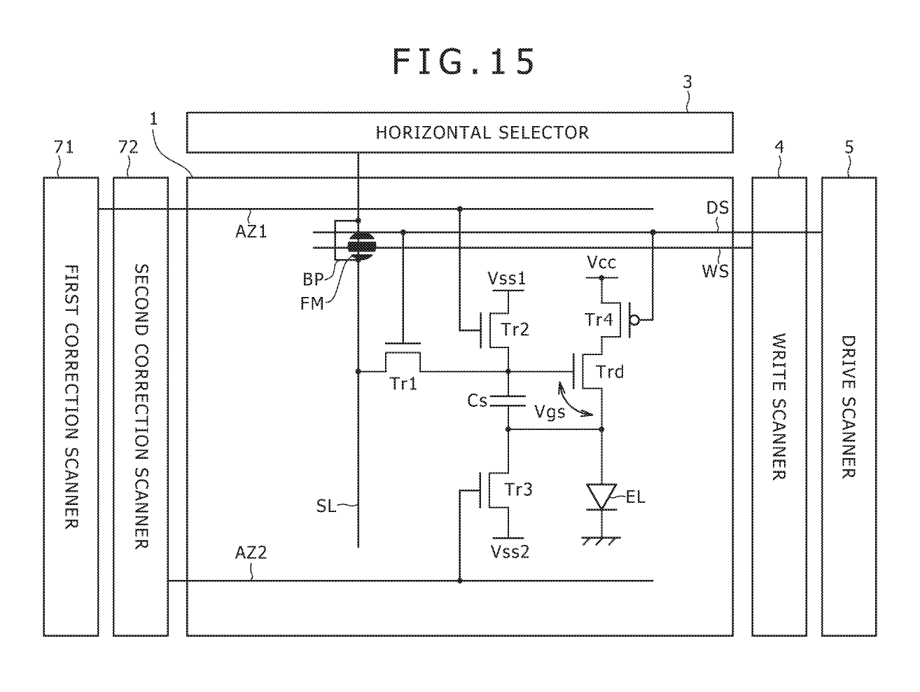

FIG. 15 shows the state obtained after the short-circuit defect FM shown in FIG. 14 is repaired by laser light irradiation. As described above, in the present embodiment, the bridge interconnect BP is so laid out as to bypass the intersections of the vertical and horizontal interconnects, which allows easy repairing of the short-circuit defect FM. Specifically, even if foreign matter is attached onto vertical and horizontal interconnects and the short-circuit defect FM is caused due to the influence of the attaching, this short-circuit defect FM can be repaired by irradiating it with laser light to thereby burn out it. In this repairing, the bridge interconnect BP is never damaged by the laser light irradiation because it bypasses the intersections. As described above, the intersection of vertical and horizontal interconnects involves a small interconnect distance and hence the highest possibility of the occurrence of a short-circuit defect. However, the feature that the bridge interconnect BP bypasses intersections allows easy repairing of a short-circuit defect at the intersections, which can provide a high panel yield.

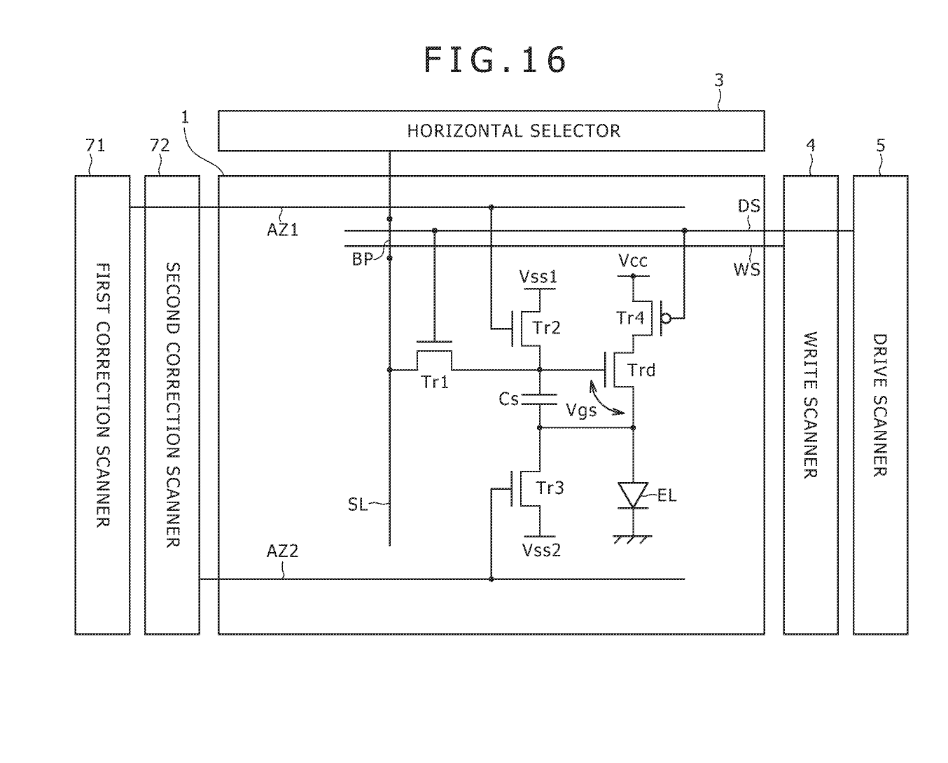

FIG. 16 is a schematic circuit diagram showing a display according to a second reference example. Basically this display is similar to the second embodiment shown in FIG. 13, and therefore the same parts in FIG. 16 as those in FIG. 13 are given the same numerals for easy understanding. The difference therebetween is that the bridge interconnect BP for connecting partial portions of the signal interconnect SL, vertically separated from each other, does not have any bypass layout but is aligned with the signal interconnect SL on a straight line. In other words, the bridge interconnect BP is so formed as not to avoid the intersections of the vertical and horizontal interconnects at all.

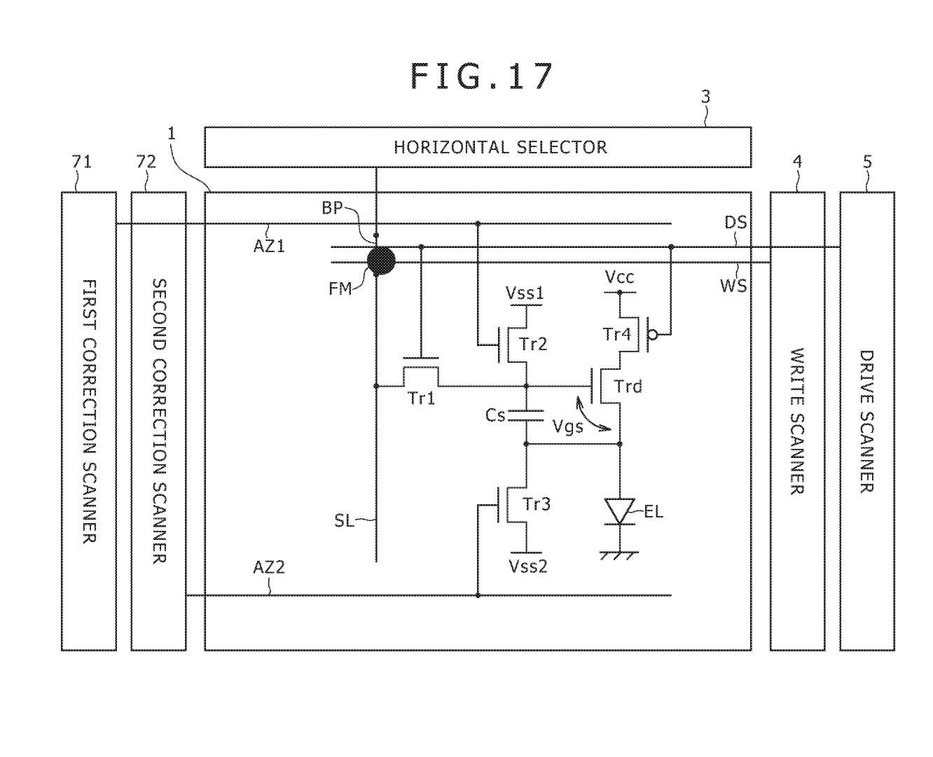

FIG. 17 shows the state in which a short-circuit defect FM is caused at intersections in the display shown in FIG. 16. In this state, the pixel array part 1 can not operate normally because the vertical interconnect SL is short-circuited with the horizontal interconnects WS and DS. In addition, the scan interconnects WS and DS parallel to each other are also short-circuited with each other, which also precludes normal operation.

Therefore, the short-circuit defect FM needs to be repaired by irradiating it with laser light to thereby burn it out. However, the bridge interconnect BP exists under the short-circuit defect FM in this second reference example. Therefore, the laser light irradiation possibly damages the bridge interconnect BP, and thus the repair treatment can not be safely carried out.

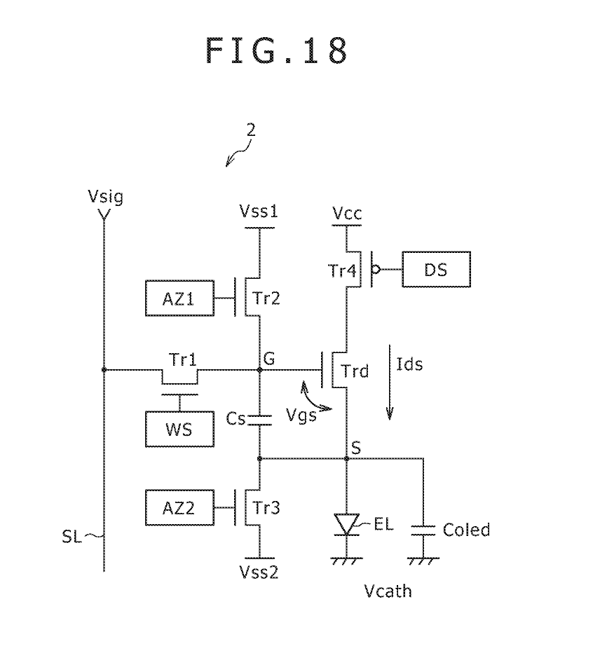

FIG. 18 is a schematic diagram focusing on the pixel circuit 2 in the display according to the second embodiment shown in FIG. 13. In order to facilitate understanding, FIG. 18 includes representation of the video signal Vsig, which is sampled through the sampling transistor Tr1, the input voltage Vgs and the output current Ids of the drive transistor Trd, and a capacitive component Coled possessed by the light-emitting element EL. The operation of the pixel circuit 2 will be described below with reference to FIG. 18.

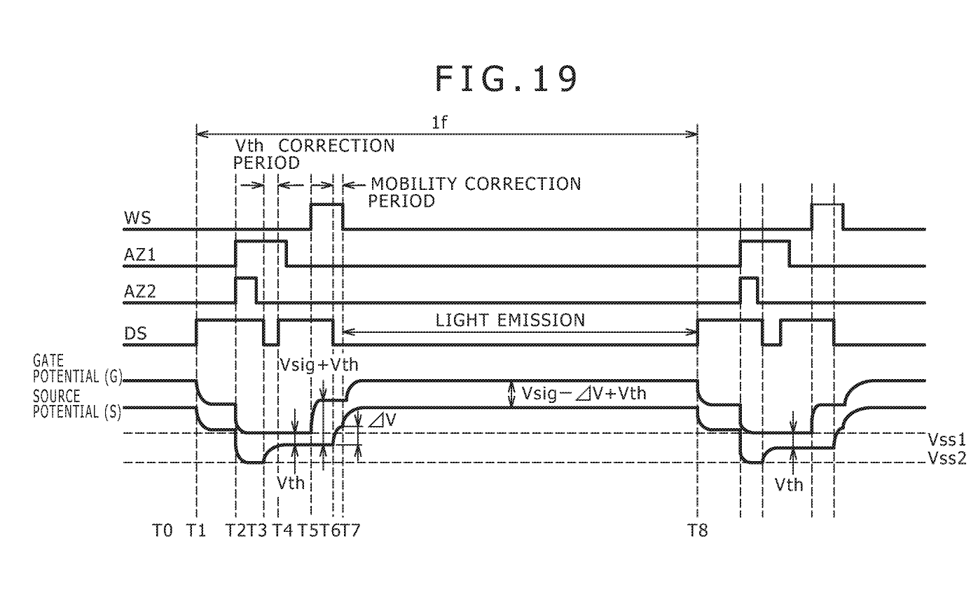

FIG. 19 is a timing chart for explaining the operation of the pixel circuit shown in FIG. 18. Details of the drive method shown in FIG. 19 will be described below. At a timing T0, which is prior to the start of the description-subject field, all the control signals WS, AZ1, AZ2, and DS are at the low level. Therefore, the N-channel transistors Tr1, Tr2, and Tr3 are in the off-state whereas only the P-channel transistor Tr4 is in the on-state. Thus, the drive transistor Trd is coupled to the power supply Vcc via the transistor Tr4 in the on-state, and therefore supplies the output current Ids to the light-emitting element EL depending on the predetermined input voltage Vgs. Accordingly, the light-emitting element EL emits light at the timing T0. The input voltage Vgs applied at this time to the drive transistor Trd is represented as the potential difference between the gate potential (G) and the source potential (S).

At a timing T1, which is the start of the description-subject field, the control signal DS is switched from the low level to the high level. This turns off the transistor Tr4, which isolates the drive transistor Trd from the power supply Vcc. Thus, the light emission is stopped and a non-light-emission period starts. That is, at the timing T1, all the transistors Tr1 to Tr4 are in the off-state.

Subsequently, at a timing T2, the control signals AZ1 and AZ2 are switched to the high level, which turns on the switching transistors Tr2 and Tr3. As a result, the gate G of the drive transistor Trd is connected to the reference potential Vss1, and the source S thereof is connected to the reference potential Vss2. The potentials Vss1 and Vss2 satisfy the relationship Vss1−Vss2>Vth. Therefore, the relationship Vss1−Vss2=Vgs>Vth is ensured, and thereby preparation for Vth correction to be carried out from a timing T3 is achieved. That is, the period T2-T3 corresponds to the reset period for the drive transistor Trd. Furthermore, the relationship VthEL>Vss2 is designed, in which VthEL denotes the threshold voltage of the light-emitting element EL. Due to this relationship, negative bias is applied to the light-emitting element EL, and therefore the light-emitting element EL is in the so-called reverse-bias state. This reverse-bias state is necessary to normally carry out Vth correction operation and mobility correction operation later.

At the timing T3, the control signal AZ2 is switched to the low level, and thereupon the control signal DS is also switched to the low level. Thus, the transistor Tr3 is turned off while the transistor Tr4 is turned on. As a result, the drain current Ids flows toward the holding capacitor Cs, so that the Vth correction operation is started. During the current flow, the potential of the gate G of the drive transistor Trd is kept at Vss1. The current Ids flows until the drive transistor Trd is cut off. At the timing of the cutting-off of the drive transistor Trd, the source potential (S) of the drive transistor Trd is Vss1−Vth. At a timing T4, which is after the cutting-off of the drain current, the control signal DS is returned to the high level again to thereby turn off the switching transistor Tr4. In addition, the control signal AZ1 is returned to the low level to thereby turn off the switching transistor Tr2. As a result, Vth is held and fixed in the holding capacitor Cs. In this manner, the threshold voltage Vth of the drive transistor Trd is detected in the period T3-T4. In the present specification, the detection period T3-T4 is referred to as a Vth correction period.

After the Vth correction is thus carried out, the control signal WS is switched to the high level at a timing T5. Thus, the sampling transistor Tr1 is tuned on to thereby write the video signal Vsig to the holding capacitor Cs. The capacitance of the holding capacitor Cs is sufficiently lower than that of the equivalent capacitor Coled of the light-emitting element EL. Consequently, most of the video signal Vsig is written to the holding capacitor Cs. To be exact, the potential difference Vsig−Vss1 is written to the holding capacitor Cs. Therefore, the voltage Vgs between the gate G and source S of the drive transistor Trd becomes the voltage (Vsig−Vss1+Vth), which results from the addition of the sampled voltage Vsig−Vss1 to the voltage Vth detected and held in advance. If the equation Vss1=0 V is employed in order to simplify the following description, the voltage Vgs between the gate and source is Vsig+Vth as shown in the timing chart of FIG. 19. The sampling of the video signal Vsig is carried out until a timing T7, at which the control signal WS is returned to the low level. That is, the period T5-T7 corresponds to the sampling period.

At a timing T6, which is prior to the timing T7 as the end timing of the sampling period, the control signal DS is switched to the low level, which turns on the switching transistor Tr4. This connects the drive transistor Trd to the power supply Vcc, so that the operation sequence of the pixel circuit proceeds to a light-emission period from the non-light-emission period. During the period T6-T7, in which the sampling transistor Tr1 is still in the on-state and the switching transistor Tr4 is in the on-state, correction relating to the mobility of the drive transistor Trd is carried out. That is, in the present example, mobility correction is carried out during the period T6-T7, in which later part of the sampling period overlaps with beginning part of the light-emission period. In the beginning part of the light-emission period for the mobility correction, in fact, the light-emitting element EL is in the reverse-bias state and therefore emits no light. In this mobility correction period T6-T7, the drain current Ids flows through the drive transistor Trd in the state in which the gate G of the drive transistor Trd is fixed at the level of the video signal Vsig. If the relationship Vss1−Vth<VthEL is designed, the light-emitting element EL is in the reverse-bias state, and therefore exhibits not a diode characteristic but a simple capacitive characteristic. Accordingly, the current Ids flowing through the drive transistor Trd is written to the capacitor C=Cs+Coled, resulting from coupling between the holding capacitor Cs and the equivalent capacitor Coled of the light-emitting element EL. This raises the source potential (S) of the drive transistor Trd. This potential rise is indicated by ΔV in the timing chart of FIG. 19. This potential rise by ΔV is eventually equivalent to subtraction of the voltage ΔV from the gate-source voltage Vgs held in the holding capacitor Cs, and thus is regarded as negative feedback. By thus negatively feeding back the output current Ids of the drive transistor Trd to the input voltage Vgs of the same drive transistor Trd, correction for the mobility μ is allowed. The negative feedback amount ΔV can be optimized by adjusting the time width of the mobility correction period T6-T7.

At the timing T7, the control signal WS is switched to the low level, which turns off the sampling transistor Tr1. As a result, the gate G of the drive transistor Trd is isolated from the signal interconnect SL. Because the application of the video signal Vsig is stopped, the gate potential (G) of the drive transistor Trd is permitted to rise up, and therefore actually rises up together with the source potential (S). During the potential rise, the gate-source voltage Vgs held in the holding capacitor Cs is kept at the value (Vsig−ΔV+Vth). The rise-up of the source potential (S) eliminates the reverse-bias state of the light-emitting element EL. Therefore, the light-emitting element EL starts actual light emission due to the flowing of the output current Ids thereto. The relationship at this time between the drain current Ids and the gate voltage Vgs is represented by the following equation.

Ids=kμ(Vgs−Vth)²=kμ(Vsig−ΔV)²

In this equation, k=(½)(W/L)Cox. W denotes the channel width of the drive transistor, L denotes the channel length of the drive transistor, and Cox denotes the gate capacitance per unit area of the drive transistor. This characteristic equation does not include the term Vth eventually, which shows that the output current Ids supplied to the light-emitting element EL has no dependence on the threshold voltage Vth of the drive transistor Trd. Basically, the drain current Ids therefore is determined by the signal voltage Vsig of the video signal. That is, the light-emitting element EL emits light with the luminance in accordance with the video signal Vsig. Furthermore, the voltage Vsig is corrected by the feedback amount ΔV. This correction amount ΔV functions to cancel the influence of the mobility μ, which exists at the coefficient part of the above equation. Consequently, the drain current Ids depends only on the video signal Vsig practically.

Finally, at a timing T8, the control signal DS is switched to the high level and thus the switching transistor Tr4 is turned off, which ends the light emission and the description-subject field. Simultaneously, the next field starts and therefore the Vth correction operation, the mobility correction operation, and the light-emission operation will be repeated again.

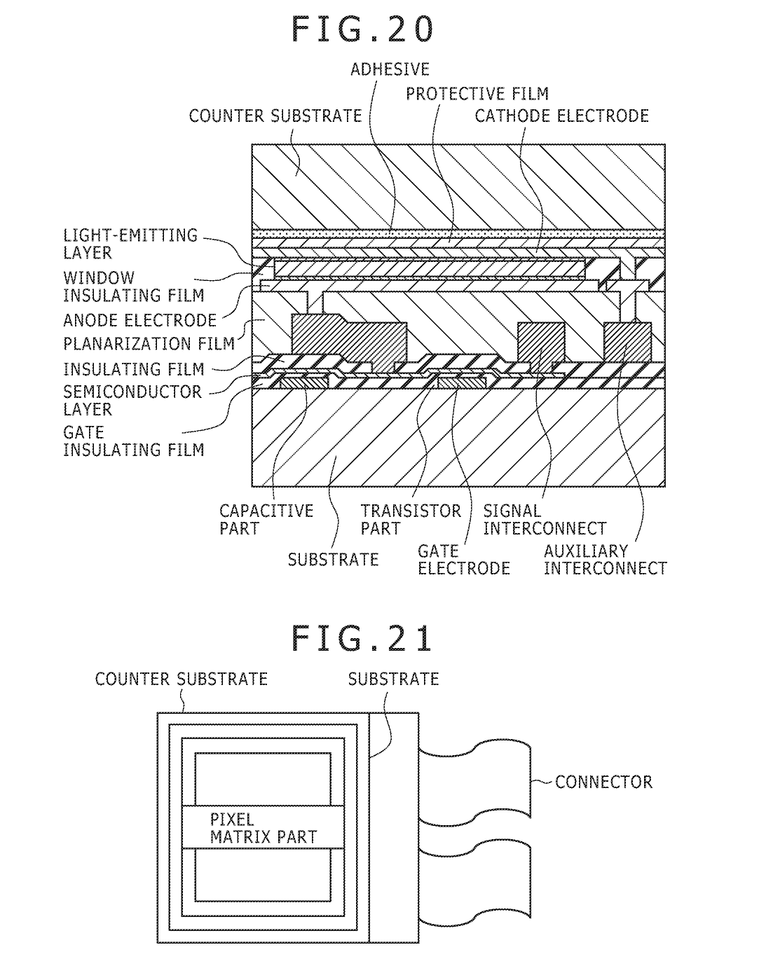

The displays according to the above-described embodiments have a thin-film device structure like that shown in FIG. 20. FIG. 20 shows a schematic sectional structure of a pixel formed on an insulating substrate. As shown in FIG. 20, the pixel includes a transistor part having plural thin film transistors (only one TFT is shown in FIG. 20), a capacitive part such as a holding capacitor, and a light-emitting part such as an organic EL element. The transistor part and the capacitive part are formed on the substrate by a TFT process, and the light-emitting part such as an organic EL element is stacked thereon. A counter substrate is attached over the light-emitting part with the intermediary of an adhesive, so that a flat panel is obtained.

The displays according to the above-described embodiments encompass a display having a flat module shape like that shown in FIG. 21. For example, the display module is obtained as follows. A pixel array part in which pixels each including an organic EL element, thin film transistors, a thin film capacitor, and so on are integrally formed into a matrix is provided on an insulating substrate. Subsequently, an adhesive is disposed to surround this pixel array part (pixel matrix part), and a counter substrate composed of glass or the like is bonded to the substrate. This transparent counter substrate may be provided with e.g. a color filer, protective film, and light-shielding film according to need. The display module may be provided with e.g. a flexible printed circuit (FPC) as a connector for inputting/outputting of signals and so forth to/from the pixel array part from/to the external.

The displays according to the above-described embodiments have a flat panel shape, and can be applied to a display unit in various kinds of electronic apparatus in any field that displays image or video based on a video signal input thereto or produced therein, such as a digital camera, notebook personal computer, cellular phone, and video camera. Examples of electronic apparatus to which such a display is applied will be described below.

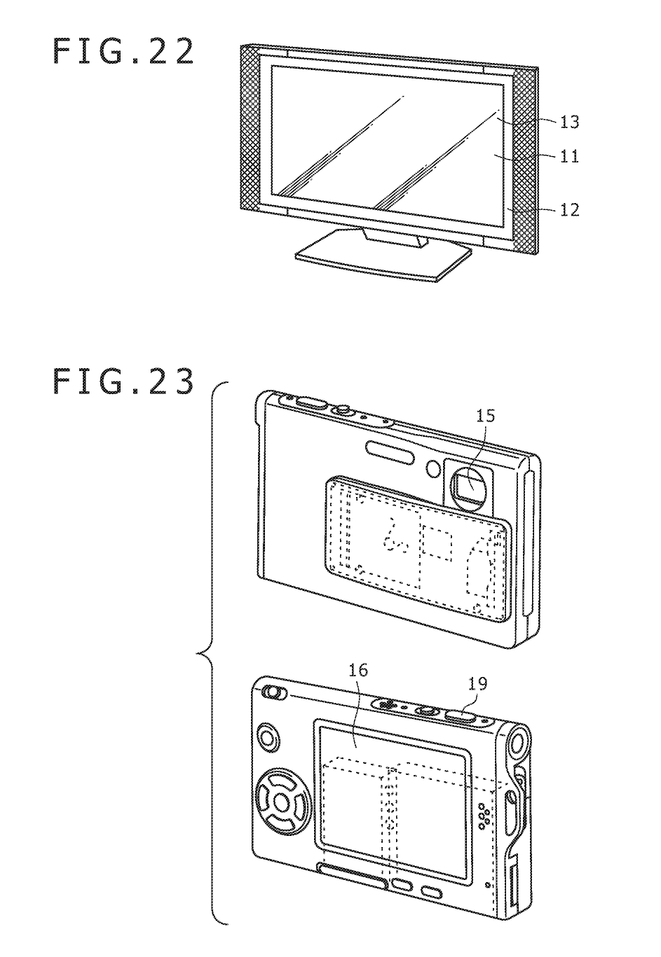

FIG. 22 shows a television to which any of the embodiments is applied. The television includes a video display screen 11 composed of a front panel 12, a filter glass 13, and so on, and is fabricated by using the display according to any of the embodiments as the video display screen 11.

FIG. 23 shows a digital camera to which any of the embodiments is applied: the upper diagram is a front view and the lower diagram is a rear view. This digital camera includes an imaging lens, a light emitter 15 for flash, a display part 16, a control switch, a menu switch, a shutter button 19, and so on, and is fabricated by using the display according to any of the embodiments as the display part 16.

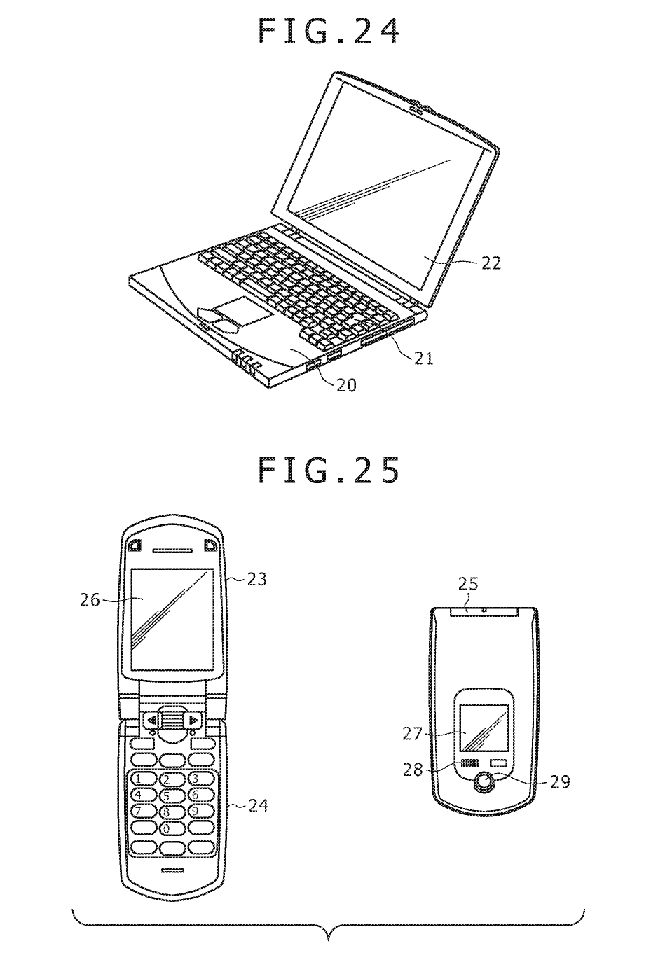

FIG. 24 shows a notebook personal computer to which any of the embodiments is applied. A main body 20 of the personal computer includes a keyboard 21 that is operated in inputting of characters and so on, and the body cover thereof includes a display part 22 that displays images. The personal computer is fabricated by using the display according to any of the embodiments as the display part 22.

FIG. 25 shows a portable terminal device to which any of the embodiments is applied: the left diagram shows the opened state and the right diagram shows the closed state. This portable terminal device includes an upper casing 23, a lower casing 24, a connection (hinge) 25, a display 26, a sub-display 27, a picture light 28, a camera 29, and so on. The portable terminal device is fabricated by using the display according to any of the embodiments as the display 26 and the sub-display 27.

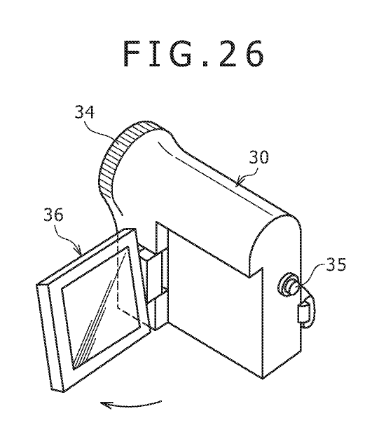

FIG. 26 shows a video camera to which any of the embodiments is applied. The video camera includes a main body 30, a lens 34 that is disposed on the front side of the camera and used to capture a subject image, a start/stop switch 35 for imaging operation, a monitor 36, and so on. The video camera is fabricated by using the display according to any of the embodiments as the monitor 36.

It is to be understood that while invention has been described in conjunction with a specific embodiment, it is evident that many alternatives, modifications and variations will become apparent to those skilled in the art in light of the foregoing description. Accordingly, it is intended that the present invention embrace all such alternatives, modifications and variations as fall within the spirit and scope of the appended claims.

What is claimed is:

1. A display device comprising:
a plurality of pixels, each of the pixels including at least a sampling transistor, a drive transistor, a holding capacitor, and a light-emitting element,
the sampling transistor being configured to be turned ON according to a control signal supplied to a gate electrode of the sampling transistor, sample a video signal, and write the video signal to the holding capacitor, and
the drive transistor being configured to supply a drive current according to the video signal written in the holding capacitor to the light-emitting element,
wherein,
in each of the pixels, first wiring extending in a first direction and second wiring extending in a second direction are formed with a same conductor layer,
the first wiring is formed to be divided into a first wiring portion and a second wiring portion with a space, and the first wiring portion and the second wiring portion are mutually connected through another wiring provided in a different layer from the conductor layer,
the second wiring is formed to pass the space and cross the first wiring,
the another wiring is arranged to cross the second wiring and avoid the space,
one of the first wiring and the second wiring includes wiring that supplies a power supply voltage to each of the pixels, and
the other of the first wiring and the second wiring includes wiring that supplies the video signal to each of the pixels.

2. The display device according to claim 1, wherein
one of the first wiring and the second wiring includes wiring that supplies the control signal to each of the pixels, and the wiring that supplies the power supply voltage to each of the pixels, and
at least the wiring that supplies the power supply voltage and the wiring that supplies the video signal are formed with the same conductor layer.

3. The display device according to claim 1, wherein
each of the pixels has a threshold voltage correction function to cancel an influence of a threshold voltage of the drive transistor.

4. The display device according to claim 1, wherein
each of the pixels has a mobility correction function to cancel an influence of mobility of the drive transistor.

5. The display device according to claim 1, wherein
the light-emitting element is an organic EL light-emitting element.

6. The display device according to claim 1, wherein
the same conductor layer is an Al wiring layer.

7. The display device according to claim 1, wherein
the different layer is an Mo wiring layer.

8. The display device according to claim 1, wherein
the first wiring includes the wiring that supplies the video signal to each of the pixels, and
the second wiring includes wiring that supplies the control signal to each of the pixels, and the wiring that supplies the power supply voltage to each of the pixels.

9. The display device according to claim 8, wherein
the another wiring crosses both of the wiring that supplies the control signal to each of the pixels and the wiring that supplies the power supply voltage to each of the pixels, the both of the wiring being included in the second wiring.

10. A method of manufacturing a display device, the method comprising:
manufacturing a pixel array portion including
a plurality of pixels, each of the pixels including at least a sampling transistor, a drive transistor, a holding capacitor, and a light-emitting element,
in each of the pixels, first wiring extending in a first direction and second wiring extending in a second direction being formed with a same conductor layer,
the first wiring being formed to be divided into a first wiring portion and a second wiring portion with a space,
the first wiring portion and the second wiring portion being mutually connected through another wiring provided in a different layer from the conductor layer,
the second wiring being formed to pass the space and cross the first wiring,
the another wiring being arranged to cross the second wiring and avoid the space,
one of the first wiring and the second wiring including wiring that supplies a power supply voltage to each of the pixels, and
the other of the first wiring and the second wiring including wiring that supplies a video signal to each of the pixels; and
performing repairing by cutting a short-circuit portion in a case where the short-circuit portion is caused between the first wiring and the second wiring in the space of any of the pixels.

11. The method of manufacturing a display device according to claim 10, wherein,
in the performing repairing, the short-circuit portion is cut by irradiating the short-circuit portion with a laser.

12. The method of manufacturing a display device according to claim 10, wherein,
in the performing repairing, the short-circuit portion is cut not to cut the another wiring.

13. The method of manufacturing a display device according to claim 11, wherein,
in the performing repairing, the short-circuit portion is irradiated with the laser, avoiding the another wiring, not to cut the another wiring.
